(19) United States
(12) Patent Application Publication
(10) Pub. No.: US 2006/0273811 A1
(43) Pub. Date: Dec. 7, 2006

(54) Using an active load as a high current output stage of a precision pin measurement unit in automatic test equipment systems

(76) Inventors: Geoffrey Haigh, Boxford, MA (US); James Wey, Arlington, MA (US)

Correspondence Address: BROMBERG & SUNSTEIN LLP, 125 SUMMER STREET, BOSTON, MA, 02110-1618, US

(21) Appl. No.: 11/437,426

(22) Filed: May 19, 2006

Related U.S. Application Data
(60) Provisional application No. 60/682,745, filed on May 19, 2005.

(51) Int. Cl. G01R 31/02

(52) U.S. Cl. 324/761

(57) ABSTRACT

A pin electronics circuit for use in automatic testing equipment that includes a load for testing a pin of a device under test. The load of the pin electronics circuit is electrically coupled to a precision parametric measurement unit. In this embodiment, the precision pin measurement unit provides a forcing signal to the load when a high current mode is desired. In response to the forcing signal, the load generates a current through a resistor that results in a desired current or voltage at a pin of the device under test. Since the load is used in high current mode, the precision parametric measurement unit does not include a high current output stage.

### CROSS REFERENCE TO RELATED APPLICATIONS

The present application claims priority from U.S. Provisional Patent Application No. 60/682,745 entitled “Use of a Load as the High Current Output Stage of a Precision Pin Measurement Unit in Automatic Test Equipment Systems,” filed on May 19, 2005, which is incorporated herein by reference in its entirety.

### TECHNICAL FIELD AND BACKGROUND ART

The present invention relates to pin electronics in automatic testing equipment and more specifically to a use of a pin electronics load as a high current output stage for a precision parametric unit. In the automatic testing equipment field (ATE), it is known to have pin electronics (that may include, for example, a load, a driver, and a comparator) associated with a channel that couple to pin of a device under test (DUT) for testing the DUT. In addition, ATE may have a precision parametric measurement unit (PPMU). The purpose of the PPMU is to perform precision measurements on the DUT. Typically, the PPMU either forces a voltage at a pin of the DUT and measures the resulting current or forces a current at a pin and measures the resulting voltage at the pin.

In order to perform these functions, the PPMU must include an output stage capable of providing currents over a wide range of values. For example, the PPMU may have an operational amplifier capable of producing a current in the range of 20 mA. As such, when the PPMU is coupled to the pin electronics with the high current source, additional capacitance (parasitic) is provided to the pin of the DUT. As a result, this additional capacitance requires that the pin electronics operate at a slower rate due to the resultant RC time constant. Further, the high current source of the PPMU takes up additional space on the integrated circuit and consumes additional power.

FIG. 1 shows a prior art pin electronic circuit 100 that includes a driver 101, comparator 102, load 103, and a PPMU 104. The PPMU 104 includes an operational amplifier 105 that is capable of outputting a range of currents including a 20 mA force signal. Typically, the PPMU 104 is capable of producing various output signals at discrete levels, for example, 1 mA, 10 mA, and 20 mA. As shown, the load 103 is implemented using a diode bridge and two controllable current sources. Each of the pin electronic elements is coupled to the pin 106 of the DUT; hence the load 103, PPMU 104, and comparator 102 each contribute to the load capacitance 108. Control circuitry 109, such as a digital-to-analog converter produces the control signals to the driver, load, and PPMU and a measurement circuit 110 including an analog-to-digital converter that measures the output signal from the sense amplifier of the PPMU.

FIG. 2 shows additional detail of the pin electronics 200 and more specifically, shows more detail of the PPMU 205. As constructed, the PPMU 205 contains an operational amplifier (force amp) 206 powered by two current sources (−20 mA, 20 mA) 207A, 207B. The operational amplifier 206 is coupled to a plurality of switches 208A-C wherein each switch is coupled to a resistor 210A-C of a different magnitude (50, 500, 5000 ohms). By switching between the resistances, the operational amplifier 206 can produce different currents at the output of the pin electronics 209 wherein each current is determined by the voltage output of the operational amplifier 206 divided by the resistance. If the voltage produced is approximately 0.5 V (which is full scale for the sense amplifier of the PPMU) then the representative currents would be 10 mA, 1 mA, and 0.1 mA. Between each switch and corresponding resistor is a node 211A-C. Each node is coupled to a switch 212A-C that when closed electrically couples the node to the input 214 of a sense amplifier 213. The second input 215 of the sense amplifier 213 is connected to the output node 209 of the pin electronics 200. When the force amp 206 is forcing a voltage, V, the output node 209 of the pin electronics 200 is coupled both to an input of the sense amp 215 and also to the negative terminal 216 of the force amp creating a feedback loop. This is accomplished by a pair of switches 217, 218 that are coupled to the negative terminal of the operational amplifier. When the force amp 206 is forcing a current, I, the switches are coupled such that the output of the sense amp 220 is electrically coupled to the negative terminal 216 of the force amp 206 and also to the output buffer 221. In this configuration, the output node 209 sees the parasitic capacitances produced by the internal switches of the PPMU along with the parasitic capacitance produced by the load. Thus, due to these parasitic capacitances, the operational speed of the pin electronics circuit is limited by the resultant RC time constant. Additionally, the force amp must be capable of producing an output voltage that can accommodate the largest desired current. Thus, when the smaller desired currents are required, the force amp uses excessive power.

### SUMMARY OF THE INVENTION

In a first embodiment of the invention, there is provided a pin electronics circuit that includes a load for testing a pin of a device under test. The pin electronics circuit can be used in an automatic testing equipment device and may also include a comparator and a driver, for example. The load of the pin electronics circuit is electrically coupled to a precision parametric measurement unit. In this embodiment, the precision pin measurement unit provides a forcing signal to the load when a high current mode (e.g. 20 mA) is desired. In response to the forcing signal, the load generates a current through a resistor that results in a desired current or voltage at a pin of the device under test. Since the load is used in high current mode, the basic precision parametric measurement unit does not include a high current output stage.

The precision parametric measurement unit is coupled to the load through a switching circuit that may be a multiplexor. The switching circuit receives a switch signal for switching between a forcing signal from the precision parametric measurement unit and a load signal wherein the switching circuit provides either the load signal or the forcing signal to the load. In certain embodiments, the pin electronics circuit includes control circuitry. The control circuitry produces a control signal to the precision parametric measurement unit. IN certain embodiments when the desired current from the force amplifier of the PPMU is beyond the capabilities of the force amplifier, the control circuitry causes the multiplexor to direct a forcing signal to the load.

The pin electronics circuit may also include a resistance positioned between the load and the device under test. The resistance may be sized to substantially match a resistance of a cable electrically coupled between the resistance and the device under test. In certain embodiments the load is a bridgeless load. If the pin electronics circuit includes a pin driver, the pin driver may be electrically coupled to the output of the load and the resistance.

In a force current mode, the load produces a forced current to the pin of the device under test. In a force voltage mode, the load causes a forced voltage at the pin of the device under test.

The invention may also be embodied as a method for using a load as a PPMU output stage. A control signal is received at a precision parametric measurement unit indicating that a current should be forced. The precision parametric measurement unit produces a forcing signal in response to the control signal. A switching circuit is switched so that the forcing signal is provided to the load. The load then produces the desired current. In a force I mode, the desired current is provided to the pin of the DUT. In a force V mode, the desired current produces a voltage at the pin of the DUT. In addition to producing a desired current or voltage at the pin of the device under test, the PPMU senses the resulting voltage or current at the pin. The resulting current or voltage is provided to a measurement circuit.

### BRIEF DESCRIPTION OF THE DRAWINGS

The foregoing features of the invention will be more readily understood by reference to the following detailed description, taken with reference to the accompanying drawings, in which:

FIG. 1 is a circuit schematic of a prior art pin electronics circuit;

FIG. 2 is a circuit schematic of a second prior art pin electronics circuit showing details of the precision parametric measurement unit;

FIG. 3 is a circuit schematic of a first embodiment of the invention for using a load circuit to force a current at a pin of a device under test sensed by the precision parametric measurement unit;

FIG. 4 is a circuit schematic showing a detailed embodiment of the precision parametric measurement unit and load circuitry;

FIG. 5 is a circuit schematic showing a detailed embodiment of the circuit in FIG. 4; and

FIG. 6 is a circuit schematic showing an alternative embodiment where the PPMU does not include a force amplifier and the load is used for forcing all current and voltage levels at the DUT pin.

### DETAILED DESCRIPTION OF SPECIFIC EMBODIMENTS

Embodiments of the present invention can be used in an automatic testing equipment (ATE) device. Pin electronics circuitry for ATE devices are each associated with a pin of a device under test (DUT). In typical ATE devices, multiple pin electronics circuitry is used in parallel to test hundreds to thousands of pins of DUTs. The present invention uses the pin electronics circuitry to perform some of the functionality of a precision parametric measurement unit. A precision parametric measurement unit or a per-pin parametric measurement unit (PPMU) is a test circuit that tests a pin of a DUT by either forcing a current and measuring a voltage at the pin being tested or by forcing a voltage at the pin and measuring the resulting current. In general PPMU's are designed to force currents and voltages over a wide range of values. For example, a typical PPMU may force currents ranging between 0.1 mA and 20 mA.

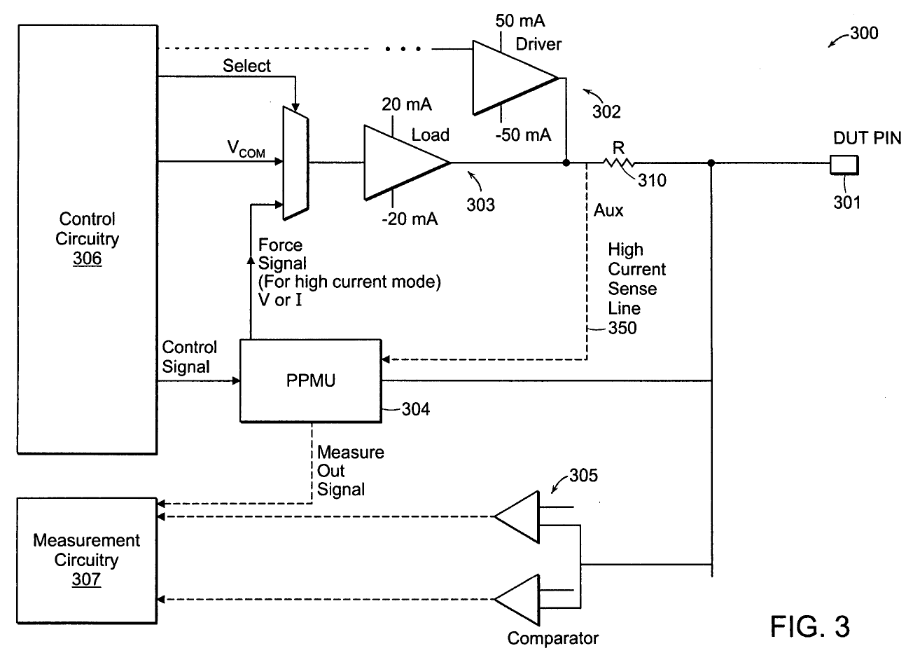

FIG. 3 is a first embodiment of the invention. The figures shows pin electronics circuitry 300 for testing a pin 301 of a DUT. The pin electronics 300 includes a driver circuit 302, a load 303, a PPMU 304, and a comparator 305. The driver 302, load 303 and PPMU 304 are controlled by control circuitry 306 and the comparator 305 outputs the comparison signal to measurement circuitry 307. The control circuitry 306 may be a digital-to-analog converter controlled by some outside signal that may originate from a processor (not shown). The measurement circuitry 307 may be an analog-to-digital converter that converts the comparison signal from the comparator into a digital representation. The analog-to-digital converter can provide the digital signal to a processor for further processing.

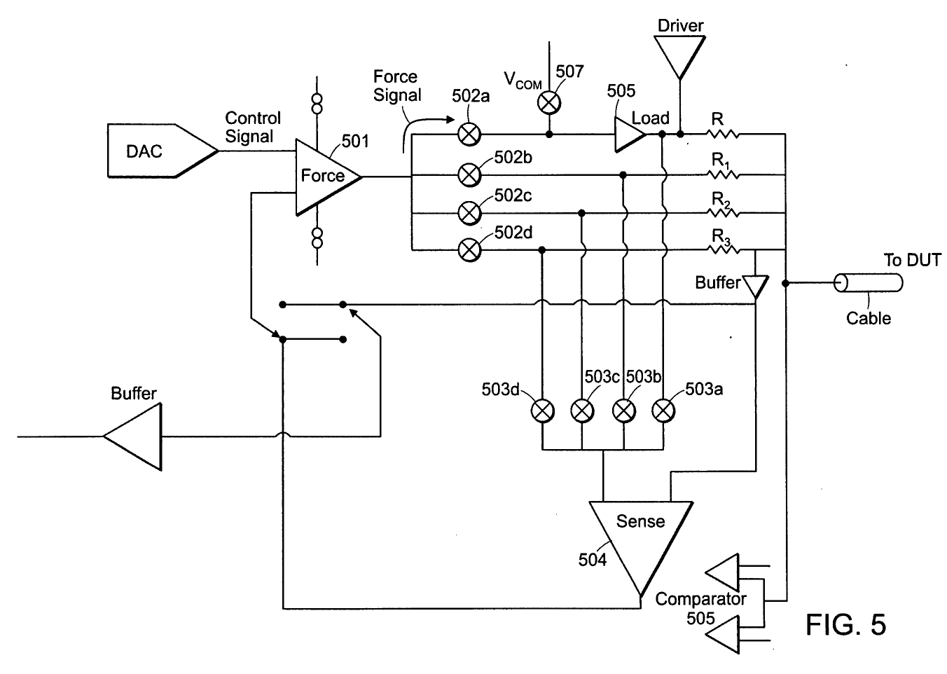

In this embodiment, the load circuit 303 of the pin electronics 300 is used as a high current output stage of a PPMU to force a current or voltage. The forced signal may be any desired value and the PPMU 304 can be configured to produce a plurality of values over a range of values as shown in FIG. 5. As implemented in FIG. 3, the PPMU 304 passes a forcing signal to the load circuit 303, so that the load circuit 303 produces a desired current value through resistor R 310. The PPMU 304 of the present embodiment of the invention does not include a high current output stage. Rather, the PPMU 304 uses the load 303 of the pin electronics to provide current to the pin of the device under test when required. The PPMU 304 may provide one or more different current signals, in order to force one or more current values or voltages at the pin of the DUT. In the present configuration, the Auxiliary high current sense line 350 is switched into the circuit when the load is used as the high current output stage. The sense signal is provided to the sense amplifier (not shown) of the PPMU).

It is more desirable to use the load for driving the current desired by the PPMU to force a current or voltage as opposed to using the driver of the pin electronics, since the load is a relative low-speed device. In contrast, the driver is a relative high-speed device. If the driver is used to drive the current of the PPMU, the connections between the PPMU and the driver create additional capacitances on the driver. As a result, when the driver is used as a driver as opposed to a current source for the PPMU, the driver experiences the additional capacitance of the connections and therefore must operate at a slower rate due to the resultant RC time constant. Therefore, it is more desirable to couple the PPMU and the load together as opposed to the PPMU and the driver.

As shown in FIG. 3 the load 302 is not directly coupled to the pin 301 of the device under test. The load 302 is coupled to the back match resistor 3 10. The back match resistor is a resistance that is equal to the resistance of the cable that couples the output node of the pin electronics with the DUT. By using a bridgeless load, as referenced below, the load need not be directly coupled to the DUT pin and therefore, the parasitic capacitance contribution of the load circuit is greatly reduced as compared to using a bridge based load that requires the load to be directly coupled to the pin. By bringing the load inside of the back match resistance, the RC time constant of the output of the pin electronics is lowered and therefore, the pin electronics can operate at higher speeds.

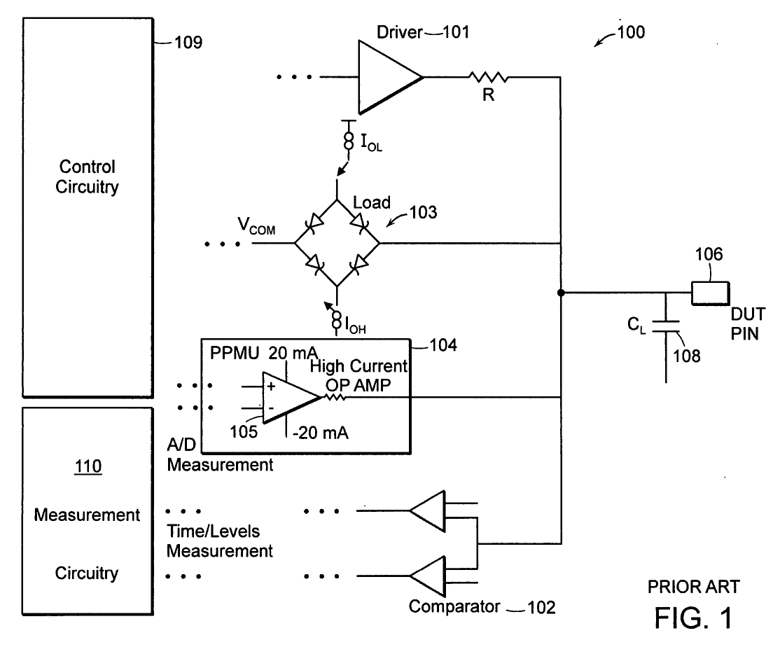

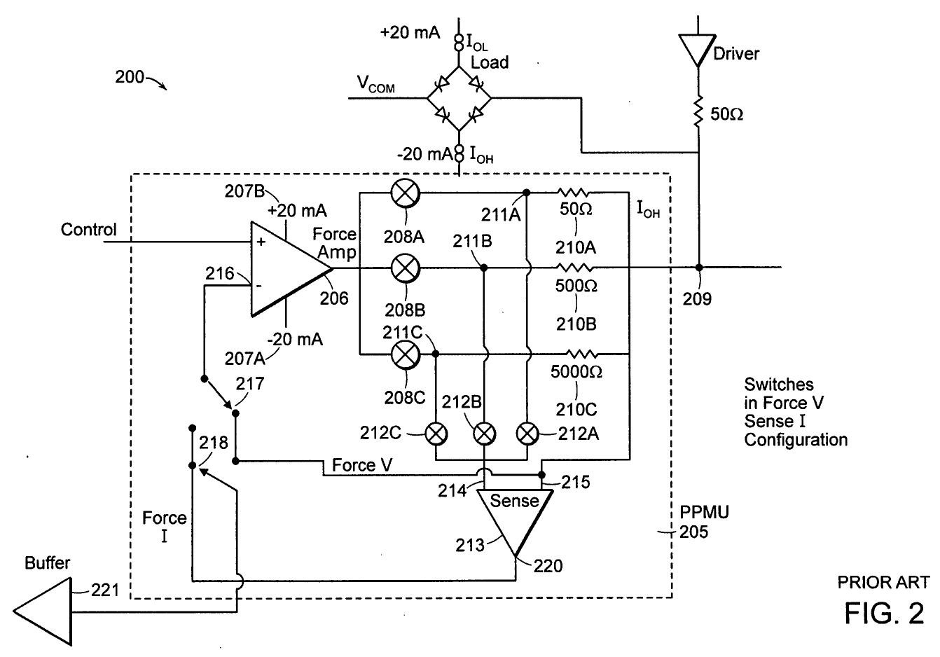

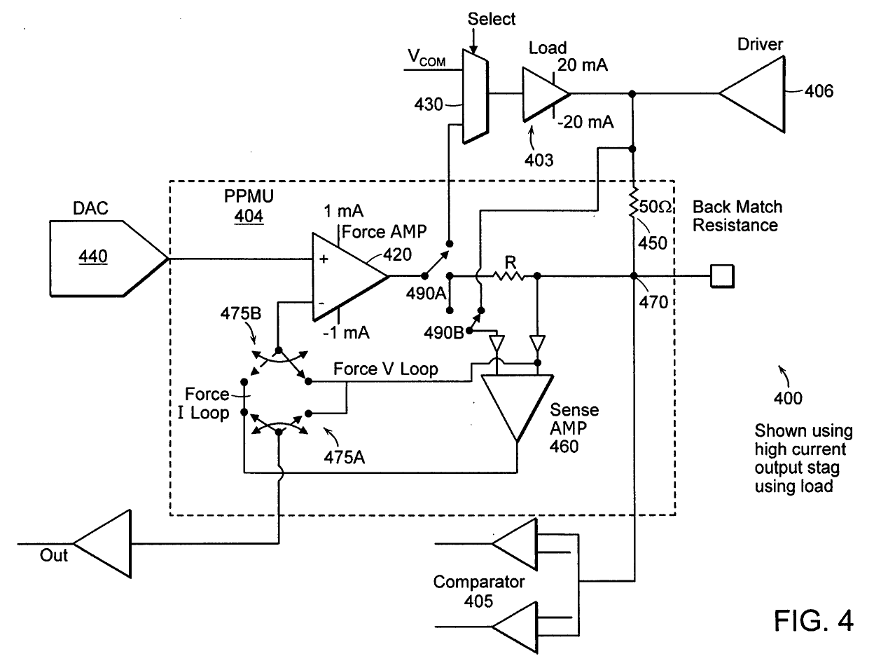

In other embodiments of the invention, the PPMU may include an operational amplifier that can produce a current through a resistor. In such an embodiment as shown in FIG. 4, the load circuit 403 forces currents at higher current levels than that of the operational amplifier 420. For example, the operational amplifier 420 may force currents in the 0.1 mA to 1 mA range, whereas the load 403 would be used for currents in the 10 mA to 20 mA range. Because the load circuit 403 of the pin electronics 400 needs to be capable of producing currents in this range of values for load purposes, additional high current circuitry is not required. As a result, power is saved because the power draw produced by the operational amplifier 420 within the PPMU 404 is lowered as compared to the prior art embodiments as shown in FIGS. 1 and 2.

The PPMU 404 is coupled to a multiplexer 430 that may be switchably selected. A select signal is sent to the multiplexer 430 selecting the PPMU forcing signal as opposed to the Vcom (commutate) for the load. As embodied, the load is a bridgeless load; however both bridged and bridgeless loads may be used with the invention. An example of a bridgeless load is described in U.S. patent application No. 11/253,071 entitled “Transconductance Stage Operating as an Active Load for Pin Electronics,” having the same assignee as the present application and which is incorporated herein by reference in its entirety.

As with FIG. 3, the pin electronics circuit of FIG. 4 includes a comparator 405, load 403, driver 406 and PPMU 404. The PPMU circuit 404 of the present embodiment includes a force amp 420. The force amp 420 is powered by current supplies that have a lower current draw than that of the load 403. For example, the force amp can draw 1/10^{th} or 1/20^{th} of the current of the load. The force amp receives input from control circuitry, which is shown as a digital-to-analog converter (DAC) 440. The DAC 440 controls the input level to the force amp 420 and as a result the output of the force amp. Thus, the DAC 440 can vary the forced current and forced voltage over a range of values where the range of values is limited by the current sources of the force amp 420. If the desired forced current/voltage is above the range capable of the force amp 420, the DAC 440 provides a control signal to the force amplifier 420 and a select signal is sent to the multiplexor 430 coupled to the output of the force amplifier 420. Additionally, switches 490A, B are switched to allow the output of the force amplifier to be directed to the multiplexer and to provide the output to of the load to an input of the sense amplifier 460. The multiplexor 430 switches between the commutation voltage signal that is normally used with the load 403 and the force signal from the PPMU. The multiplexor 430 provides the force signal to the load 403. The load 403 produces a current through the back match resistor 450 to the pin of the DUT at the desired current level. In the voltage force mode, a feedback loop is employed to force the voltage at the pin. The sense amplifier 460 of the PPMU 404 operates to sense the voltage/current at the pin 470 of the device under test. The control circuitry 440 sets the switches 475A, B in the sense loops so that the force I loop or force V loop is active. The voltage or current at the pin of the device under test is sensed by the sense amplifier 460 and provided through the buffer to the output.

In this embodiment, the load 403 and the driver 406 are not directly coupled to the output pin 470 and they both reside behind the back match resistor 450 thereby decreasing the capacitive load at the output pin. As a result, the present pin electronics circuit may operate at higher speeds than that of the prior art.

FIG. 5 shows an alternative embodiment wherein the PPMU can force different currents and voltages at the pin of the device under test depending on the size of the connected resistance. The force amplifier is coupled to a plurality of switches 502a-d that can be controllably switched. When one of the switches 502b-d is switched, a current is generated through the appropriately sized resistor (R1-3). Thus, the force amplifier can generate different current and voltage levels at the pin of the device under test. Additionally, the load circuitry is used to generate a current outside of the range of currents that the force amplifier can generate. Thus, when a desired forced current level is outside of the range of currents that the force amplifier can generate, control circuitry causes switch 502a to be switched closed and switch 507 disconnects Vcom, so that the force amplifier is coupled to the load. The force amplifier produces a force signal to the load and the load generates a current through resistor R. In certain embodiments resistor R is a back match resistor that matches to the cables resistance that couples the pin electronics circuitry to the pin of the device under test. A typical value for the back match resistance is 50 Ohms.

Additionally, switches 503a-d are correspondingly switched with switches 502a-d, so that the voltage can be sensed by the sense amplifier across the corresponding resistance R-R3 when in force I sense V mode. Similarly, in force V sense I, the sense amplifier senses the current.

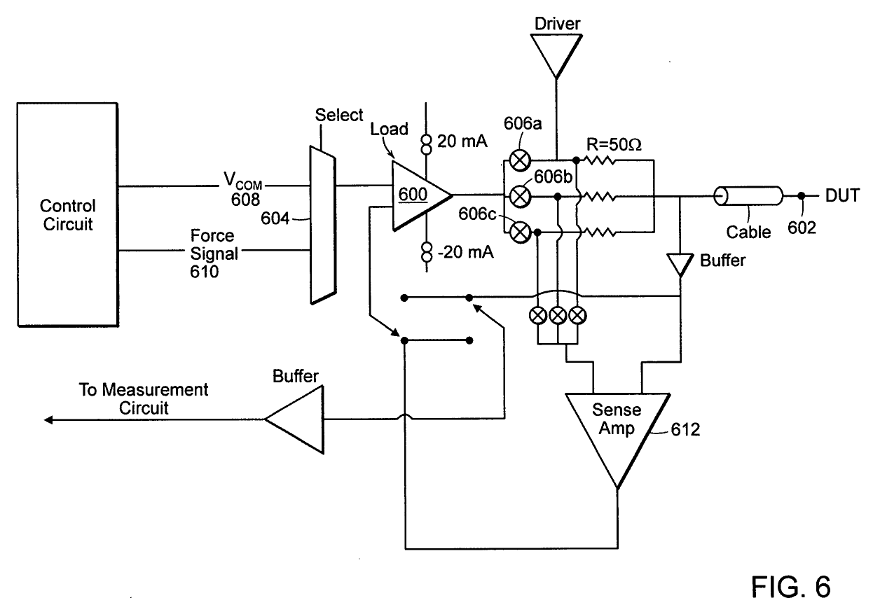

FIG. 6 is a circuit schematic showing an alternative embodiment where the PPMU does not include a force amplifier and the load 600 is used for forcing all current and voltage levels at the DUT pin 602. The embodiment of FIG. 6 operates similarly to the embodiment of FIG. 5. In the present configuration, a multiplexor 604 either passes a force signal 610 or a commutation voltage 608 to the load 600. If a select signal is provided to the multiplexor 604 selecting the force signal 610, the appropriate switch 606a-c coupled to the desired resistance is switched. Thus, in the embodiment that is shown, for a force signal 610 at a given level, three different current levels can be produced depending on the switch 606a-c that is switched. If the load 600 is operating as a load as opposed to a force amplifier, the commutation voltage 608 is provided to an input of the load 600. The first switch 606a is switched thereby coupling the output of the load 600 to resistance R. In this configuration, the sense amplifier 612 can either be disconnected by turning off the current supplies that power the amplifier or the sense amplifier may be used to sense a resulting signal at the DUT pin.

Although various exemplary embodiments of the invention have been disclosed, it should be apparent to those skilled in the art that various changes and modifications can be made which will achieve some of the advantages of the invention without departing from the true scope of the invention. These and other obvious modifications are intended to be covered by the appended claims.

What is claimed is:

1. A pin electronics circuit for use in automatic test equipment, the pin electronics circuit comprising:
a load having an output capable of being electrically coupled to a device under test;
a switching circuit capable of receiving a switch signal for switching between a forcing signal from a precision parametric measurement unit and a load signal wherein the switching circuit provides either the load signal or the forcing signal to the load.

2. The pin electronics circuit according to claim 1, further comprising:
a precision parametric measurement unit.

3. The pin electronics circuit according to claim 2, further comprising:
control circuitry producing a control signal to the precision parametric measurement unit for forcing a current beyond the capabilities of a force amplifier within the precision parametric measurement unit.

4. The pin electronics circuit according to claim 1, further comprising:
a resistance positioned between the load and the device under test.

5. The pin electronics circuit according to claim 4 wherein the resistance substantially matches a resistance of a cable electrically coupled between the resistance and the device under test.

6. The pin electronics circuit according to claim 5 wherein the load is a bridgeless load.

7. The pin electronics circuit according to claim 6 further comprising:
a pin driver electrically coupled to the output of the load and the resistance.

8. The pin electronics circuit according to claim 7 wherein the resistance is electrically between the device under test and the pin driver.

9. The pin electronics circuit according to claim 1, wherein the load produces a forced current to the pin of the device under test.

10. The pin electronics circuit according to claim 1, wherein the load causes a forced voltage at the pin of the device under test.

11. The pin electronics circuit according to claim 1, wherein the switching circuit is a multiplexor.

12. The pin electronics circuit according to claim 1, wherein the load signal is a commutation voltage.

13. A method for using a load of a pin electronics circuit in automatic test equipment to force a desired current, the method comprising:
receiving a control signal at a precision parametric measurement unit indicating that a current should be forced;
producing at the precision parametric measurement unit a forcing signal in response to the control signal;
signaling a switching circuit to switch so that the forcing signal is provided to the load; and
producing the desired current as a result of the load.

14. A method for using a load of a pin electronics circuit further comprising:
producing a desired current at a pin of a device under test.

15. A method for using a load of a pin electronics circuit further comprising:
producing a desired voltage at a pin of a device under test.

16. A method for using a load of a pin electronics circuit according to claim 14 further comprising:
sensing the voltage at the pin of the device under test using the parametric measurement unit resulting from the desired current produced by the load.

17. A method for using a load of a pin electronics circuit according to claim 15 further comprising:
sensing the current at the pin of the device under test using the parametric measurement unit resulting from the desired voltage resulting from the load.

18. A method for using a load of a pin electronics circuit according to claim 13 wherein the switching circuit switches between a commutation voltage signal and the forcing signal.

19. A method for using a load of a pin electronics circuit according to claim 13 wherein the precision parametric measurement unit includes a force amplifier and wherein the desired current at the pin of device under test is beyond the capabilities of the force amplifier.

20. A method for using a load of a pin electronics circuit according to claim 13 wherein the load is a bridgeless load.
